(19) United States
(12) Patent Application Publication
(10) Pub. No.: US 2026/0173677 A1
(43) Pub. Date: Jun. 18, 2026

(54) BACKLIT VEHICLE PANEL AND BADGE ARRANGEMENTS

(71) Applicant: Magna Exteriors Inc., Aurora (CA)

(72) Inventors: Daniel VANDER SLUIS, Rochester Hills, MI (US); Mark T. Pilette, Oxford, MI (US); Mark J. HESS, Gaines, MI (US); Bradley COX, Clifford, MI (US)

(73) Assignee: Magna Exteriors Inc., Aurora, ON (CA)

(21) Appl. No.: 18/884,998

(22) PCT Filed: Mar. 23, 2023
(86) PCT No.: PCT/US2023/016084

§ 371 Date: Sep. 13, 2024

Related U.S. Application Data
(60) Provisional application No. 63/333,650, filed on Apr. 22, 2022.

(51) Int. Cl. H10K 59/131; B60Q 1/26; F21S 41/20; F21V 8/00; F21Y 115/10

(52) U.S. Cl. CPC H10K 59/131; B60Q 1/2696; F21S 41/285; G02B 6/0031; G02B 6/006; F21Y 2115/10

(57) ABSTRACT

A vehicle panel arrangement that has a first appearance during the daylight but is capable of being backlight in a dark environment causing the badge to have a second appearance as light is transmitted through micro-apertures formed through the vehicle panel arrangement. The vehicle panel arrangement is such that the micro-apertures a not visible in the first appearance due to their small size, which is created using laser ablation, screen printing or digital printing techniques.

### FIELD OF THE INVENTION

The present invention relates to a backlit vehicle panel arrangement formed using laser ablation and digital printing techniques.

### BACKGROUND OF THE INVENTION

In the field of automotive design, lighting units have made it possible to expand the aesthetics and functionality of the automobile. Providing panels capable of having different or changing appearances is desirable. There is a need to provide vehicle panel arrangements that have a first appearance when not illuminated but have a second appearance when a light source is illuminated so as to transmit light through one side of the vehicle panel. Another area of improvement of the aesthetics of the automobile involves forming vehicle panel arrangement that are specifically badge arrangements or emblems employed on a vehicle. In particular it is desirable to provide a badge that when viewed in daylight looks like a typical non-illuminated badge, but in a dark environment the badge is connected to a light unit that illuminates the badge.

### SUMMARY OF THE INVENTION

One embodiment of the present invention is directed to providing a vehicle panel arrangement that has a first appearance when not backlit, but when a light source is illuminated the vehicle panel arrangement has a second appearance as light is transmitted through micro-apertures formed in the vehicle panel arrangement. The micro-apertures that are not visible in the first appearance due to their small size, which is created using laser ablation, screen printing or digital printing techniques.

A second embodiment of the invention is directed to a vehicle panel arrangement, which has a plurality of micro-apertures forming a light pattern suitable for being backlit by a light source. In one specific application the vehicle panel arrangement is a badge arrangement, which includes a desired name or symbol. Some badge arrangements are sometimes referred to as emblems or ornaments, while other badge arrangements are part of a vehicle panel either on the interior or exterior of the vehicle, all of which are within the scope of the invention. The badge arrangement includes a body having a light receiving surface side that receives light from the light source. The light source can be any type of light source including, but not limited to an incandescent bulb, light emitting diode and organic light emitting diode. The body is formed from polymer material that is transparent or semi-transparent and allows the light from the light source to pass through the body. Connected to the body is a metalized film layer that is light transmissible. A masking layer connects to a portion of the metallized film layer. The masking layer blocks the light transmitting through the metallized film layer from passing through the masking layer. An argent color layer is connected to a portion of the masking layer. The vehicle panel arrangement further includes a plurality of micro-apertures extending through the argent color layer and the masking layer so that the light from the light source is able to transmit through the body, metallized film layer and the plurality of micro-apertures, while the light is blocked from transmitting through the masking layer.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

The present invention will become more fully understood from the detailed description and the accompanying drawings, wherein:

FIG. 1 is a schematic cross-sectional elevational view of a portion of a badge arrangement according to one embodiment of the invention.

FIG. 2 has several schematic cross-sectional elevational views of the badge arrangement according to several embodiments of the invention.

FIG. 3A is a schematic cross-sectional elevational view of a badge arrangement according to a second embodiment of the invention.

FIG. 3B is an enlarged schematic cross-sectional elevational view of the badge arrangement of FIG. 3A.

FIG. 4 is a schematic diagram showing a method of forming an badge arrangement using laser ablation.

FIG. 5 is a front perspective view of a vehicle having a vehicle panel arrangement specifically as a backlit badge arrangement.

FIG. 6 is a partial side perspective view of a vehicle with a vehicle panel arrangement on the front fender of the vehicle.

FIG. 7 is a schematic cross-sectional elevational view of a portion of the vehicle panel arrangement.

FIG. 8 is an enlarged view of one of the micro-apertures of FIG. 7.

### DETAILED DESCRIPTION OF THE PREFERRED EMBODIMENTS

The following description of the preferred embodiments is merely exemplary in nature and is in no way intended to limit the invention, its application, or uses.

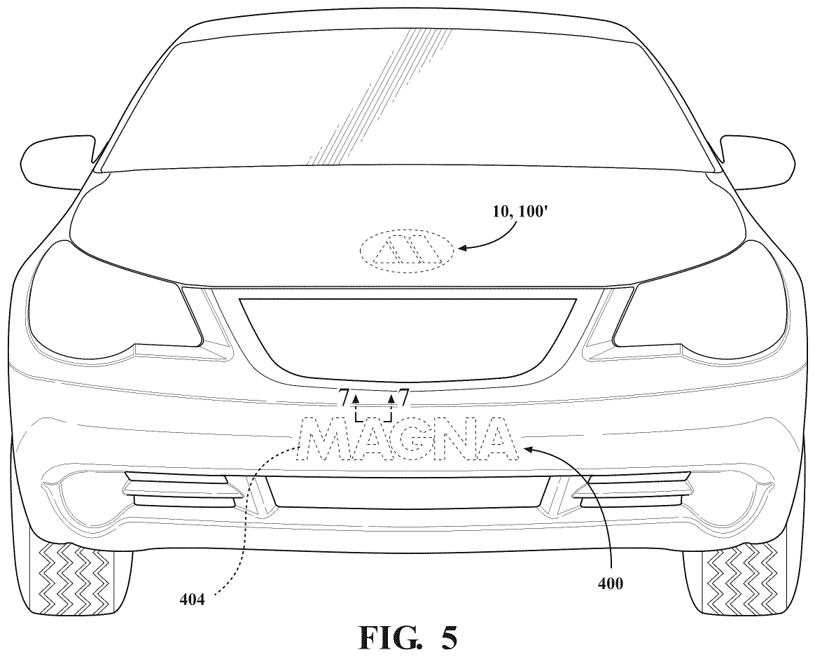

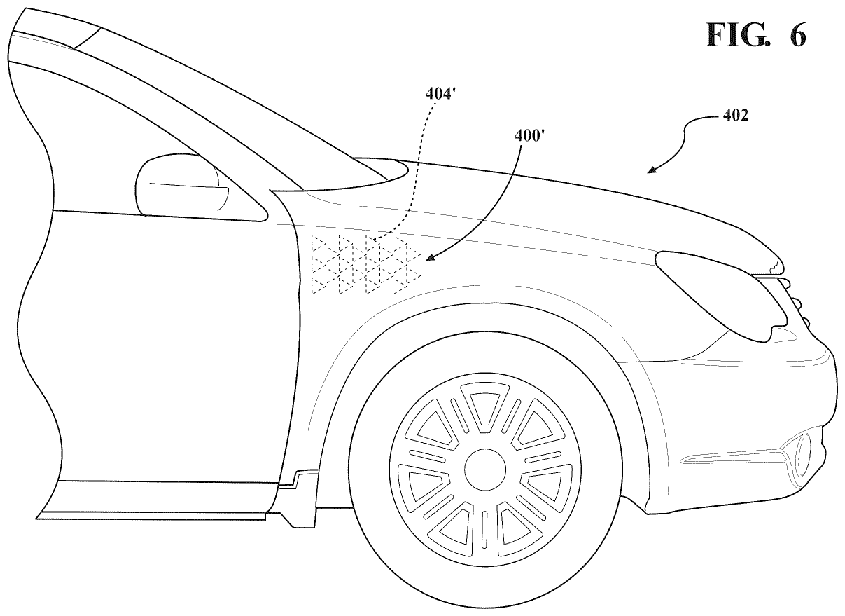

Referring now to FIGS. 5 and 6 a vehicle panel arrangement 400, 400′ shown as part of a vehicle 402. The vehicle panel arrangement 400 is part of a front fascia, while vehicle panel arrangement 400′ shown in FIG. 6 is a front fender of the vehicle 402. It is within the scope of this invention for the vehicle panel arrangement to be part of any vehicle surface where backlit illumination is desired. The vehicle panel arrangement 400, 400′ and has an illumination surface 404, 404′ that can be backlit by a light source (described below). The illumination surface 404 of the vehicle panel arrangement 400 shows letters when illuminated but is not visible when the light source is turned off. Illumination surface 404′ of vehicle panel arrangement 400′ shows a pattern when illuminated but is not visible when the light source is turned off. FIG. 5 also shows a vehicle panel arrangement that is specifically a badge arrangement 10, 100. The badge arrangement 10, 100 is a type of vehicle panel arrangement, but differs from the vehicle panel arrangement 400, 400′ in that they are emblems or ornaments connected to surface on the vehicle exterior or interior. Also, the construction of the vehicle panel arrangement 400, 400′ can differ slightly from the construction of the badge arrangement 10, 100.

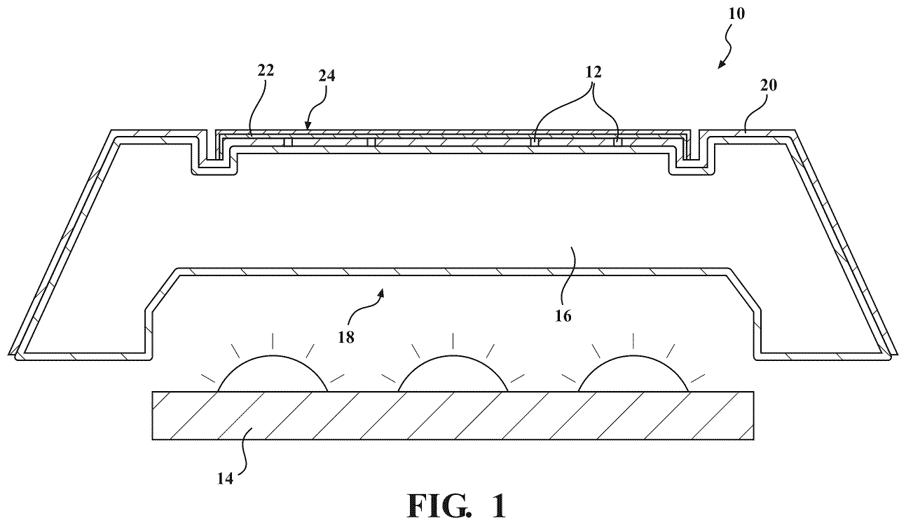

Referring now to FIG. 1 the badge arrangement 10 is shown having a plurality of micro-apertures 12 forming a light pattern suitable for being backlit by a light source 14. The badge arrangement 10 includes a body 16 having a light receiving surface side 18 that receives light from the light source 14. The light source 14 is singular or plural and is any type of light source including, but not limited to an incandescent bulb, light emitting diode and organic light emitting diode.

The body 16 is formed from polymer material that is transparent or semi-transparent and allows the light from the light source to pass through the body 16. Connected to the body 16 is a metalized film layer 20 that is light transmissible. A masking layer 22 connects to a portion of the metallized film layer 20. The masking layer 22 blocks the light transmitting through the metallized film layer 20 from passing through the masking layer 22. The masking layer 22 is made of any type of opaque material and can be an opaque paint film or paint layer that is applied to the metalized film layer 20.

The badge arrangement 10 further includes an argent color layer 24 connected to a portion of the masking layer 22. The argent color layer 24 is a layer of paint or paint film that has argent color properties. Argent as used herein includes colors that have a metallic look and are somewhat reflective, which helps conceal the micro-apertures 12.

The badge arrangement 10 further includes a plurality of micro-apertures 12 extending through the argent color layer 24 and the masking layer 22. Light from the light source 14 is able to transmit through the body 16, metallized film layer 20 and the plurality of micro-apertures 12. The light is blocked from transmitting through the masking layer 22. The plurality of micro-apertures 12 each have a certain diameter that is generally between 30 microns to 80 microns in diameter. It is also within the scope of this invention for the micro-apertures 12 to be less than or equal to 60 microns in diameter or greater than or equal to 60 microns in diameter all depending on the needs of a particular application. The spacing of the micro-apertures 12 is referred to as the pitch which is the distance between the center of a first one of the plurality of micro-apertures and the center of an a second one of the plurality of micro-apertures. The pitch in one embodiment of the invention is 300 microns between each of the micro-apertures 12.

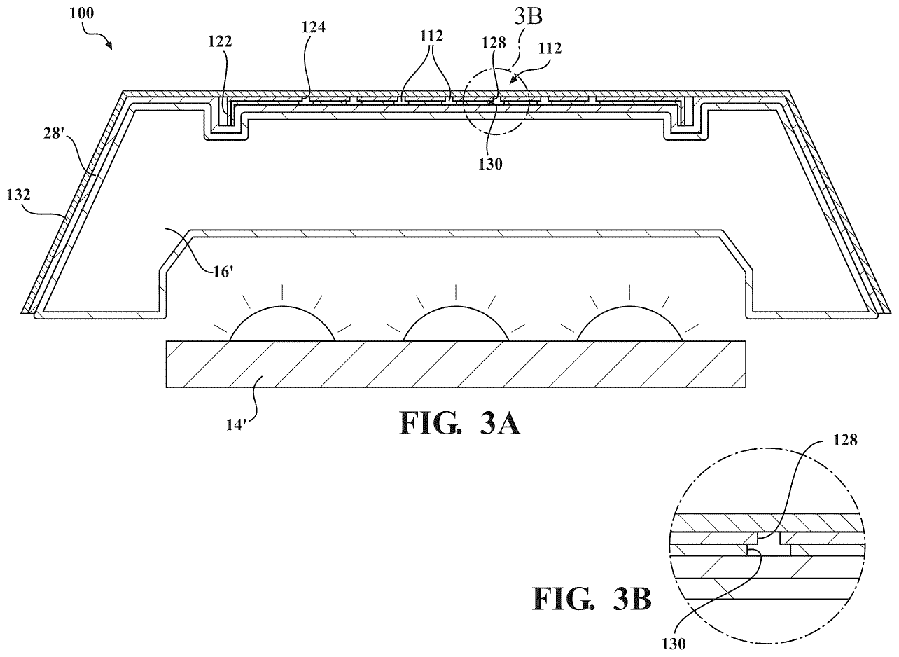

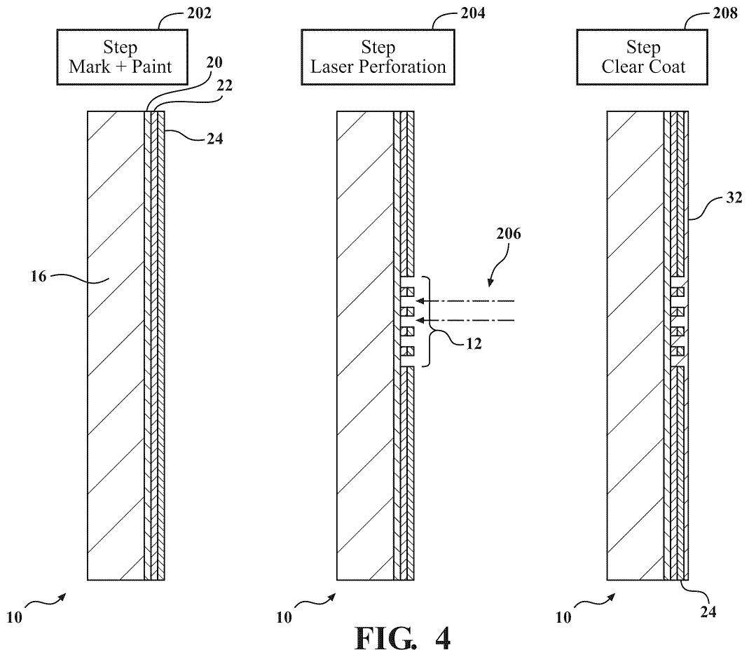

Referring now to FIGS. 3A and 3B there is the badge arrangement 100 that is formed with micro-apertures 112 that have a unique formation. This embodiment has a light sources 14′, which has one or more light emitting sources, a body 16 and metalized film layer 20′. In this embodiment a masking layer 122, and argent color layer 124 are applied using digital printing or screen printing, sometimes called silk screen printing, which are applied in successive steps. Laser ablation is not used to form the micro-apertures, instead micro-apertures 112 are formed by during the printing of the masking layer 122 and the argent color layer 124. Each micro-aperture 112 includes an argent color layer aperture 128 formed through the argent color layer 124 and aligned with a masking layer aperture 130 formed through the masking layer 122. It can be difficult to align the making layer aperture 130 and the argent color layer aperture 128. The masking layer aperture 130 has a larger diameter than the argent color layer aperture 128. This accounts for possible printing errors or misalignments between the masking layer aperture 130 and the argent color layer aperture 128.

In another embodiment of the invention the badge arrangement 10, 100 further includes a lens 32, 132 connected over the body 16, 16′, metalized film layer 20, 20′ masking layer 22, 122 and argent color layer 24, 124. The lens 32, 132 can be made of any material as long as it is light transmissible. The lens 32, 132 can be a separately molded piece that is connected or can be a layer of material that is sprayed onto the badge arrangement 10, 100. In one embodiment the lens 32, 132 is made of a self-leveling polymer. The lens 32, 132 an also be made polyurethane. The lens 32, 132 can also be constructed to be able to magnify the at least a portion of the argent color layer 24, 124 when viewed from a viewing surface of the lens 32, 132. In another aspect of the invention the lens 32, 132 is constructed to be able to minimize the at least a portion of the argent color layer 24, 124 when viewed from a viewing surface of the lens 32, 132.

Referring now to FIG. 4 a schematic diagram showing a method 200 of forming the badge arrangement 10 using laser ablation is shown. The first step 202 involves providing the body 16 with the metalized film layer 20, masking layer 22, argent color layer 24 applied in layers on to the body 16. At a step 204 laser beams 206 are projected at and ablate portions of the argent floor layer 14 and masking layer 22 for form the micro-apertures 12 at desired locations. At a step a layer of clear coating material, such as polyurethane is applied to the surface to form the lens 32. The lens 32 covers the micro-apertures 12 the argent floor layer with the masking layer 22, metalized film layer 20 and body 16 underneath. In areas where the body 16 and metalized film layer 20 are only exposed the lens 32 is formed over the metalized film layer 20.

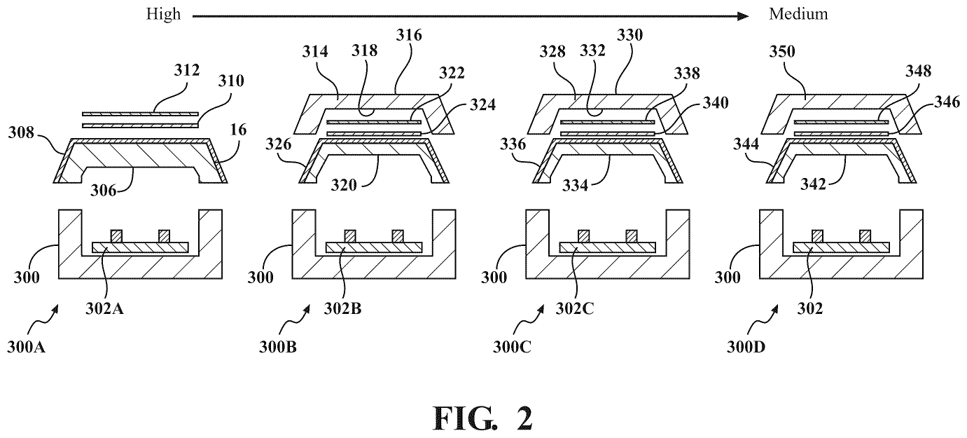

FIG. 2 has several schematic cross-sectional elevational views of the badge arrangement according to several embodiments of the invention. In each embodiment of the invention there is a connection surface 300A, 300B, 300C, 300D and light source 302A, 302B, 302C, 302D connected to the connection surface 300.

According to one embodiment an automotive assembly construction 304A there is a body 306 with a metalized layer 308 applied to the show surface, which is called the A side of the body 306. The metalized layer 308 is applied using vapor deposition or some other suitable method including applying a film layer. Light from the light source 302 is able to pass through the metalized layer 308. An opaque masking layer 310 is applied over a portion of the metalized layer 308. The opaque masking layer 310 in one embodiment is a layer of black paint or black paint film, however it any suitable opaque material is within the scope of the invention. Over a portion of the opaque masking layer 310 is an argent color layer 312. The argent color layer 312 can be liquid paint applied by spraying or brushing, or the argent color layer can be a layer of paint film. Laser ablation is then used to create micro-apertures in the same manner as the micro-apertures 12 are formed in FIG. 4 described above. The laser is used to create holes through the argent color layer 312 and the opaque masking layer 310.

The automotive assembly construction 300B has a lens 314 with a show side 316, also called an A side, and a back side 318 that is called a B side. The lens 314 is a clear material that is connected to a body 320 and is formed if a clear transparent material, such as polyurethane or polyacrylic. The body 320 has a metalized layer 326 applied to the exterior surface. Some light is able to pass through the metalized layer 326. The back side 318 of the lens 314 is first coated with an argent color layer 322, followed by an opaque material layer 324. The opaque material 324 and the argent color layer 322 are then ablated using a laser that directs light toward the back side 318 of the lens 314 and creates micro-apertures similar to micro-apertures 12 in the embodiments described above. After ablation the lens 314 is then connected to the body 320.

The automotive assembly construction 300C has a lens 328 with a show side 330, also called an A side, and a back side 332 that is called a B side. The lens 328 is a polyurethane lens having a magnification between the back side 332 and the show side 330, which allows for the micro-apertures formed to be smaller and less noticeable. The lens 328 is a clear material and is connected to a body 334. The body 334 has a metalized layer 336 applied to the exterior surface. Some light is able to pass through the metalized layer 336. The back side 332 of the lens 328 is first coated with an argent color layer 338, followed by an opaque material layer 340. The opaque material 340 and the argent color layer 338 are then ablated using a laser that directs light toward the back side 332 of the lens 328 and creates micro-apertures similar to micro-apertures 12 in the embodiments described above. After ablation the lens 328 is then connected to the body 334.

The automotive assembly construction 304D is different from the above three automotive assemblies in that it utilizes printing to create the micro-apertures rather than ablation. There is a body 342 with a metalized layer 344 applied to the show surface, which is called the A side of the body 342. The metalized layer 344 is applied using vapor deposition or other suitable method. Light from the light source 302 is able to pass through the metalized layer 344. An opaque masking layer 346 is applied over a portion of the metalized layer 344. The opaque masking layer 346 in one embodiment is a layer of black paint or black paint film, however it any suitable opaque material is within the scope of the invention. Over a portion of the opaque masking layer 346 is an argent color layer 348. The argent color layer 348 can be liquid paint applied by spraying or brushing, or the argent color layer can be a layer of paint film. In this embodiment the opaque masking layer 346 and the argent color layer 348 are applied using a printer that prints a pattern on the surface of the body 342. Micro apertures are printed and aligned as each layer is printed. This eliminates the need for laser ablation and also saves costs by reducing equipment and energy used. Light from the light source 302 passes through the body 334, the metalized layer 336 and the micro-apertures to illuminate the automotive assembly construction 304D. A lens 350 that is formed from polyurethane, polyacrylic or other suitable material is applied over the exposed portions of the body 342, metalized layer 344, opaque masking layer 346 and argent color layer 348 to provide protection to the layers underneath and to provide a smooth finish.

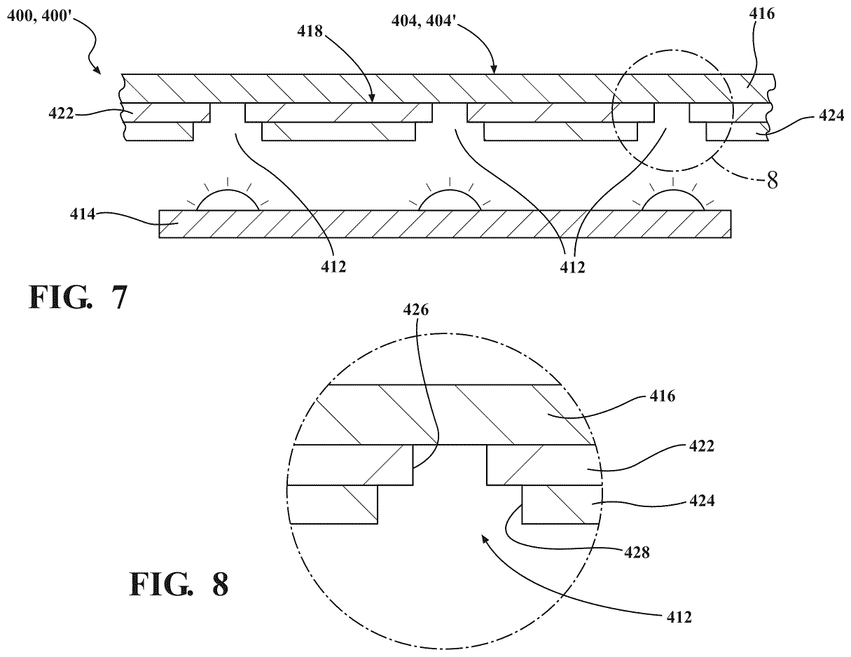

Referring now to FIG. 7 a cross-sectional side view of the vehicle panel arrangement 400, 400′ is shown. The vehicle panel arrangement 400, 400′ has a plurality of micro-apertures 412 forming a light pattern suitable for being backlit by a light source 414. The vehicle panel arrangement 400, 400′ includes a body 416 having a light receiving surface side 418 that receives light from a light source 414 and the illumination surface 404, 404′. The light source 414 is singular or plural and is any type of light source including, but not limited to an incandescent bulb, light emitting diode and organic light emitting diode.

The body 416 is formed from polymer material that is transparent or semi-transparent and allows the light from the light source to pass through the body 416 and be emitted from the illumination surface 404, 404′. A color layer 422 is applied to the light receiving surface side 418. The color layer 422 is a layer or paint or paint films that is visible from the illumination surface 404, 404′. The color layer is optionally light transmissible. A masking layer 424 connects to all of or a portion of the color layer 422. The masking layer 424 blocks light from transmitting through the color layer 422. The masking layer 424 is made of any type of opaque material and can be an opaque paint film or paint layer that is applied to the color layer 422.

The vehicle panel arrangement 400, 400′ further includes a plurality of micro-apertures 412 extending through the color layer 422 and the masking layer 424. Light from the light source 414 is able to transmit through the plurality of micro-apertures 412. The light is blocked from transmitting through the masking layer 424. The plurality of micro-apertures 412 each have a certain diameter that is generally between 30 microns to 80 microns in diameter. It is also within the scope of this invention for the micro-apertures 412 to be less than or equal to 60 microns in diameter or greater than or equal to 60 microns in diameter all depending on the needs of a particular application. The spacing of the micro-apertures 412 is referred to as the pitch which is the distance between the center of a first one of the plurality of micro-apertures and the center of an a second one of the plurality of micro-apertures. The pitch in one embodiment of the invention is 300 microns between each of the micro-apertures 412.

The micro-apertures 412 in one embodiment are formed using laser ablation similar to the techniques described above. It is also within the scope of this invention for the color layer 422 and the masking layer 424 to be printed with apertures that align as shown in FIG. 8. FIG. 8 is an enlarged view of one of the micro-apertures 412 that is formed using printing. Each aperture 412 is formed by aligning a color layer aperture 426 and a masking layer aperture 428. Since the color layer 422 is printed first and the masking layer 424 is printed second, it is possible for the color layer aperture 426 and the making layer aperture 428 to become misaligned. In order to prevent misalignment the color layer aperture 426 is smaller in diameter than the diameter of a masking layer aperture 428. The difference in diameters allow for a margin of error and make it easier for creating consistent looking micro-aperture 412.

The description of the invention is merely exemplary in nature and, thus, variations that do not depart from the gist of the invention are intended to be within the scope of the invention. Such variations are not to be regarded as a departure from the spirit and scope of the invention.

What is claimed is:

1. A vehicle panel arrangement comprising:
a body having a light receiving surface side and a viewing side;
a color layer connected to the light receiving surface side of the body;
a masking layer connected to portion of the color layer;
a plurality of micro-apertures extending through the color layer and the masking layer.

2. The vehicle panel arrangement of claim 1 further comprising:
a light source for selectively projecting light;
wherein the masking layer blocks the light transmitting through the masking layer;
wherein light from the light source passes through the plurality of micro-apertures;
wherein the light receiving surface side of the body receives light from the light source transmitted through the plurality of micro-apertures and the body is transparent and allows the light from the light source transmitted through the plurality of micro-apertures to pass through the body.

3. The badge arrangement of claim 1 wherein each of the plurality of micro-apertures is between 30 microns to 80 microns in diameter.

4. The badge arrangement of claim 1 wherein each of the plurality of micro-apertures is less than or equal to 60 microns in diameter.

5. The badge arrangement of claim 1 wherein each of the plurality of micro-apertures is greater than or equal to 60 microns in diameter.

6. The badge arrangement of claim 1 wherein the distance between the center of a first one of the plurality of micro-apertures and the center of an a second one of the plurality of micro-apertures adjacent the first one of the plurality of micro-apertures is less than or equal to 300 microns.

7. The badge arrangement of claim 1 wherein each of the plurality of micro-apertures include a color layer aperture formed through the color layer and aligned with a masking layer aperture formed through the masking layer, wherein the masking layer aperture has a larger diameter than the argent color layer aperture.

8. A badge arrangement comprising:
a body having a light receiving surface side;
a metalized film layer connected to the body, wherein the metalized film layer is light transmissible;
a masking layer connect portion of the metallized film layer;
an argent color layer connected to a portion of the masking layer;
a plurality of micro-apertures extending through the argent color layer and the masking layer.

9. The badge arrangements of claim 8 further comprising:
a light source for selectively projecting light;
wherein the light receiving surface side of the body receives light from the light source and the body is transparent and allows the light from the light source to pass through the body;
wherein the masking layer blocks the light transmitting through the metallized film layer from passing through the masking layer;
wherein the light from the light source is able to transmit through the body, metallized film layer and the plurality of micro-apertures while the light is blocked from transmitting through the masking layer.

10. The badge arrangement of claim 8 wherein each of the plurality of micro-apertures is between 30 microns to 80 microns in diameter.

11. The badge arrangement of claim 8 wherein each of the plurality of micro-apertures is less than or equal to 60 microns in diameter.

12. The badge arrangement of claim 8 wherein each of the plurality of micro-apertures is greater than or equal to 60 microns in diameter.

13. The badge arrangement of claim 8 wherein the distance between the center of a first one of the plurality of micro-apertures and the center of an a second one of the plurality of micro-apertures adjacent the first one of the plurality of micro-apertures is less than or equal to 300 microns.

14. The badge arrangement of claim 8 wherein each of the plurality of micro-apertures include an argent color layer aperture formed through the argent color layer and aligned with a masking layer aperture formed through the masking layer, wherein the masking layer aperture has a larger diameter than the argent color layer aperture.

15. The badge arrangement of claim 8 further comprising a lens connected over the body, metalized film layer, masking layer and argent color layer.

16. The badge arrangement of claim 15 wherein the lens is made of polyurethane.

17. The badge arrangement layer of claim 15 wherein the lens is able to magnify the at least a portion of the argent color layer when viewed from a viewing surface of the lens.

18. The badge arrangement layer of claim 15 wherein the lens is able to minimize the at least a portion of the argent color layer when viewed from a viewing surface of the lens.

19. A method of making a badge arrangement comprising the steps of:
providing a light source for selectively projecting light;
providing a body having a light receiving surface side that receives light from the light source, the body is transparent and allows the light from the light source to pass through the body;
providing a metalized film layer, wherein the metalized film layer is light transmissible;
connecting the metalized film layer to the body;
providing a masking layer, wherein the masking layer blocks the light transmitting through the metallized film layer from passing through the masking layer;
applying the making layer to a portion of the metallized film layer providing an argent color layer;
applying the argent color layer to a portion of the masking layer;
providing a laser with a beam capable of creating holes through the masking layer and the argent color layer;
activating the laser and forming a plurality of micro-apertures extending through the argent color layer and the masking layer so that the light from the light source is able to transmit through the body, metallized film layer and the plurality of micro-apertures while the light is blocked from transmitting through the masking layer, and
connecting the body to the light source so that light from the light source is projected through the body, metalized film layer and the plurality of micro-apertures.

20. The method of making the badge arrangement of claim 19 further comprising the steps of:
providing a lens;
connecting the lens to the body, metalized film layer, masking layer and argent color layer.

21. The method of making the badge arrangement of claim 20 wherein the lens is able to magnify the at least a portion of the argent color layer when viewed from a viewing surface of the lens.

22. The method of making the badge arrangement of claim 20 wherein the lens is able to minimize the at least a portion of the argent color layer when viewed from a viewing surface of the lens.

23. A method of making a badge arrangement comprising the steps of:
providing a light source for selectively projecting light;
providing a body having a light receiving surface side that receives light from the light source, the body is transparent and allows the light from the light source to pass through the body;
providing a metalized film layer, wherein the metalized film layer is light transmissible;
connecting the metalized film layer to the body;
providing a printer that is programmed to print a masking layer pattern and an argent color layer pattern, wherein the printer includes a masking ink and an argent color ink;
placing the body with the metalized film layer at a location where the printer is able to print the masking layer patter and the argent color pattern;
operating the printer to print a masking layer in the masking layer pattern onto the metalized film layer, wherein the masking layer blocks the light transmitting through the metallized film layer from passing through the masking layer;
operating the printer to print an argent color layer in the argent color layer pattern onto the masking layer, wherein a plurality of micro-apertures extending through the argent color layer and the masking layer are formed by the masking layer pattern and the argent color layer patter overlapping, and the light from the light source is able to transmit through the body, metallized film layer and the plurality of micro-apertures while the light is blocked from transmitting through the masking layer, and
connecting the body to the light source so that light from the light source is projected through the body, metalized film layer and the plurality of micro-apertures.

24. The method of making the badge arrangement of claim 23 further comprising the steps of:
providing a lens;
connecting the lens to the body, metalized film layer, masking layer and argent color layer.

25. The method of making the badge arrangement of claim 24 wherein the lens is able to magnify the at least a portion of the argent color layer when viewed from a viewing surface of the lens.

26. The method of making the badge arrangement of claim 25 wherein the lens is able to minimize the at least a portion of the argent color layer when viewed from a viewing surface of the lens.
